(19) United States
(12) Patent Application Publication
(10) Pub. No.: US 2024/0387396 A1
(43) Pub. Date: Nov. 21, 2024

(54) SURFACE FINISHES FOR CONTACTS AND FIDUCIAL MARKERS ON INTEGRATED CIRCUIT PACKAGE SUBSTRATES AND ASSOCIATED METHODS

(71) Applicant: Intel Corporation, Santa Clara, CA (US)

(72) Inventors: Jung Kyu Han, Chandler, AZ (US); Gang Duan, Chandler, AZ (US); Srinivas Pietambaram, Chandler, AZ (US)

(21) Appl. No.: 18/319,164

(22) Filed: May 17, 2023

(51) Int. Cl. H01L 23/544; H01L 21/48; H01L 23/00; H01L 23/498

(52) U.S. Cl. CPC H01L 23/544; H01L 21/4853; H01L 23/49811; H01L 24/11; H01L 24/13; H01L 24/16; H01L 2223/54426; H01L 2224/11462; H01L 2224/11464; H01L 2224/11849; H01L 2224/13021; H01L 2224/13111; H01L 2224/16227

(57) ABSTRACT

Surface finishes for contacts and fiducial marks on integrated circuit package substrates and associated methods are disclosed. An example integrated circuit (IC) package substrate includes a first solder resist layer; a second solder resist layer opposite the first solder resist layer; and a fiducial marker including tin in an opening in the first solder resist layer.

### FIELD OF THE DISCLOSURE

This disclosure relates generally to integrated circuit packages and, more particularly, to surface finishes for contacts and fiducial marks on integrated circuit package substrates and associated methods.

### BACKGROUND

Integrated circuit (IC) chips and/or semiconductor dies are routinely connected to larger circuit boards such as motherboards and other types of printed circuit boards (PCBs) via a package substrate. Integrated circuit (IC) chips and/or dies have exhibited reductions in size and increases in interconnect densities as technology has advanced.

### BRIEF DESCRIPTION OF THE DRAWINGS

FIG. 1 illustrates an example integrated circuit (IC) package on a printed circuit board.

FIG. 2 is a cross-sectional view of an example package substrate that may be implemented in the IC package of FIG. 1.

FIGS. 3-8 illustrate different stages in an example process of manufacturing an example package substrate that may be implemented for the example package substrate of FIGS. 1 and/or 2.

FIG. 9 is a flowchart representative of an example method of manufacturing the example package substrates of FIGS. 1-8.

FIG. 10 is a top view of a wafer including dies that may be included in an IC package constructed in accordance with teachings disclosed herein.

FIG. 11 is a cross-sectional side view of an IC device that may be included in an IC package constructed in accordance with teachings disclosed herein.

FIG. 12 is a cross-sectional side view of an IC device assembly that may include an IC package constructed in accordance with teachings disclosed herein.

FIG. 13 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Integrated circuit packages typically include a package substrate that includes a core with a series of build-up layers on one or both sides of the core. The build-up layers include multiple layers of a conductive metal defining electrical routing or traces that are separated by layers of a dielectric material. Separate ones of the conductive layers are interconnected by metal vias extending through the intervening layer(s) of dielectric material. The outer surfaces (e.g., the top and bottom) of a package substrate typically include a plurality of openings within a solder resist layer that expose portions of the outermost layer of the conductive metal of the build-up layers. Many of the exposed portions of the conductive metal serve as interconnects (e.g., bumps, pads, lands, etc.) to enable the coupling of electrical components (e.g., semiconductor die(s), capacitor(s), etc.) to the package substrate and/or to enable the electrical coupling of the package substrate to a printed circuit board. Additionally, at least some of the exposed portions of the conductive metal serve as fiducial markers to facilitate the alignment of the electrical components when being attached to the package substrate.

Frequently, the conductive metal used within the build-up layers is copper. However, in many instances, the portions of the conductive metal (e.g., copper) at the outer surfaces of a package substrate (e.g., exposed by the openings in the solder resist layer) are treated or covered by a surface finish, which may serve as a diffusion barrier. A common surface finish for exposed copper pads or contacts includes nickel. In many instances, the surface finish for the copper also includes a layer of palladium and/or a layer of gold. Typically, a surface finish of nickel, palladium, and gold is achieved through electroless plating processes. Such processes result in the formation of hydrogen bubbles in the surface finish layers that result in voids that can undermine the mechanical and/or electrical properties of the materials. Accordingly, during the electroless plating processes, package substrates typically undergo a rock and shock operation in which the substrates are disturbed or stressed by abrupt acceleration changes (e.g., shocked) to dislodge and/or release the hydrogen bubbles, thereby reducing (e.g., avoiding) the formation of voids.

While the rock and shock operations typically involved for the electroless plating of a Ni/Pd/Au surface finish is suitable for package substrates having organic cores, such operations present problems for package substrates with glass cores. Glass cores are implemented in package substrates because glass cores provide both mechanical and electrical benefits over organic cores. Specifically, it is possible to achieve smaller pitches to achieve greater scaling and associated electrical benefits while at the same time providing increased structural support for a package. Despite these advantages, glass cores also present certain challenges. Among other things, glass is relatively brittle and so is liable to break. It is for this reason that the rock and shock operation associated with traditional surface finish plating processes are not suitable for package substrates with glass cores. Examples disclosed herein overcome this concern by providing a surface finish on copper pads that includes tin without a discrete layer at least one of nickel, palladium, or gold. That is, while there may be traces of one or more of nickel, palladium, or gold, in examples disclosed herein, the traces are insufficient to be demarcated as a discrete layer. In some examples, a tin-based surface finish include no layers and/or no traces of any of the nickel, palladium or gold. In some examples, the tin used for the surface finish is substantially pure tin. As used herein, substantially pure tin means at least 99 wt % tin. In some examples, the tin-based surface finish includes a tin alloy. Tin can be deposited onto copper through electroless plating processes, similar to nickel, palladium, and gold. However, unlike the electroless plating of nickel, palladium, and/or gold, the electroless plating of tin does not produce hydrogen bubbles and, therefore, does not require the implementation of a rock and shock operation. As a result, in accordance with teachings disclosed herein, a tin-based surface finish can be applied to copper pads on the surfaces of a package substrate that includes a glass core without concern of damage to the glass core. While examples disclosed herein are described with reference to package substrates having glass cores, teachings disclosed herein can also be used in connection with package substrates having organic cores.

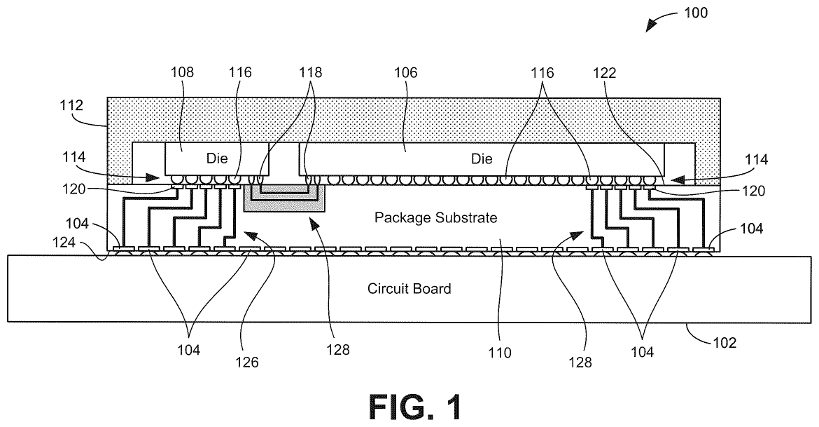

FIG. 1 illustrates an example integrated circuit (IC) package (e.g., a semiconductor package) 100 constructed in accordance with teachings disclosed herein. In the illustrated example, the IC package 100 is electrically coupled to a circuit board 102 via an array of contact pads or lands 104 on a mounting surface (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.). Further, in some examples, the IC package 100 includes other electrical components (e.g., capacitors) mounted to the package substrate 110 adjacent the semiconductor dies 106, 108.

In the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, core bumps 116 and bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the outer surface 124 (e.g., bottom surface, external surface) of the substrate 110 (e.g., a surface opposite the inner surface 122) via internal interconnects 126 within the substrate 110. As a result, there is a complete signal path between the bumps 116 of the dies 106, 108 and the landing pads 104 mounted to the circuit board 102 that pass through the contact pads 120 and the interconnects 126 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., the interconnect bridge 128 of FIG. 1) embedded in an underlying substrate (e.g., the package substrate 110). As represented in FIG. 1, core bumps 116 are typically larger than bridge bumps 118. In some examples, the interconnect bridge 128 and the associated bridge bumps 118 are omitted.

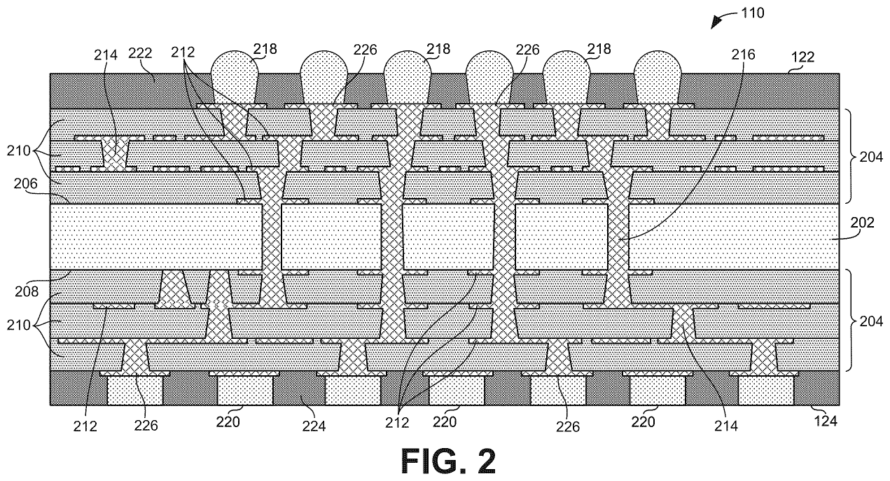

FIG. 2 is a cross-sectional view providing further detail for an example implementation of the example package substrate 110 of FIG. 1. The package substrate 110 of the illustrated example includes a glass substrate or core 202 between two separate build-up layers or regions 204. In some examples, the glass core 202 includes quartz, fused silica, and/or borosilicate glass. In accordance with the present disclosure, glass cores (e.g., the core 202) include at least one glass layer and does not include an epoxy-based prepreg layer with a glass cloth.

In the illustrated example, the build-up regions 204 are provided on a first surface 206 of the glass core 202 and a second surface 208 of the glass core 202 opposite the first surface 206. The build-up regions 204 of the illustrated example are defined by an alternating pattern of insulation of dielectric layers 210 and patterned conductive (e.g., metal) layers 212. In some examples, the conductive layers 212 include copper. In this example, there are three dielectric layers 210 and three conductive layers 212 in the build-up regions 204 (not including the outermost layer of conductive material). However, in other examples, any other suitable number of dielectric and conductive layers 210, 212 may be employed. In some examples, the build-up region 204 on at least one side of the glass core 202 may be omitted such that the glass core defines an exterior surface of the package substrate 110. Although the glass core 202 of the example package substrate 110 is shown as a central core of the substrate 110, in some examples, the glass core 202 can be an interposer and/or any other layer of the package substrate 110. For example, the glass core 202 can be used in place of one or more of the dielectric layers 210 of the package substrate 110. In some examples, the package substrate 110 can include different material(s) including organic materials, silicon, and/or other conventional materials for fabricating package substrates.

The conductive layers 212 in the build-up regions 204 are patterned to define electrical routing or conductive traces that serve as signaling or transmission lines to transfer power and/or signals of information between two or more components (e.g., transistors, capacitors, resistors, backend layers, etc. and/or other circuitry) of an associated IC package (e.g., the IC package 100 of FIG. 1). Electrically conductive (e.g., metal) vias 214 extend through the dielectric layers 210 to electrically couple different ones of the conductive layers 212 in the different build-up regions 204. Further, as shown in FIG. 2, the glass core 202 of the illustrated example includes one or more through glass vias (TGVs) 216 (e.g., copper plated vias) that extend between the opposite surfaces 206, 208 of the glass core 202 to communicatively and/or electrically couple the conductive layers 212 and associated metal vias 214 within the build-up regions 204 on either side of the glass core 202. Thus, in this example, the electrical routing or traces defined by the patterning of the conductive layers 212, the conductive vias 214, and the TGVs 216 collectively define electrical interconnects (e.g., the interconnects 126 of FIG. 1) through the substrate 110.

In the illustrated example, the package substrate 110 includes a first plurality of connectors 218 (e.g., solder balls, bumps, contact pads, pins, etc.) on the inner surface 122 of the substrate 110 to electrically couple the package substrate 110 to one or more semiconductor die (e.g., one of the dies 106, 108 of FIG. 1) and/or any other suitable component (e.g., an interposer). Further, the example package substrate 110 includes a second plurality of connectors 220 (e.g., solder balls, bumps, contact pads, pins, etc.) on the outer surface 124 to electrically couple the package substrate 110 to a printed circuit board (e.g., the circuit board 102 of FIG. 1), an interposer and/or any other substrate(s).

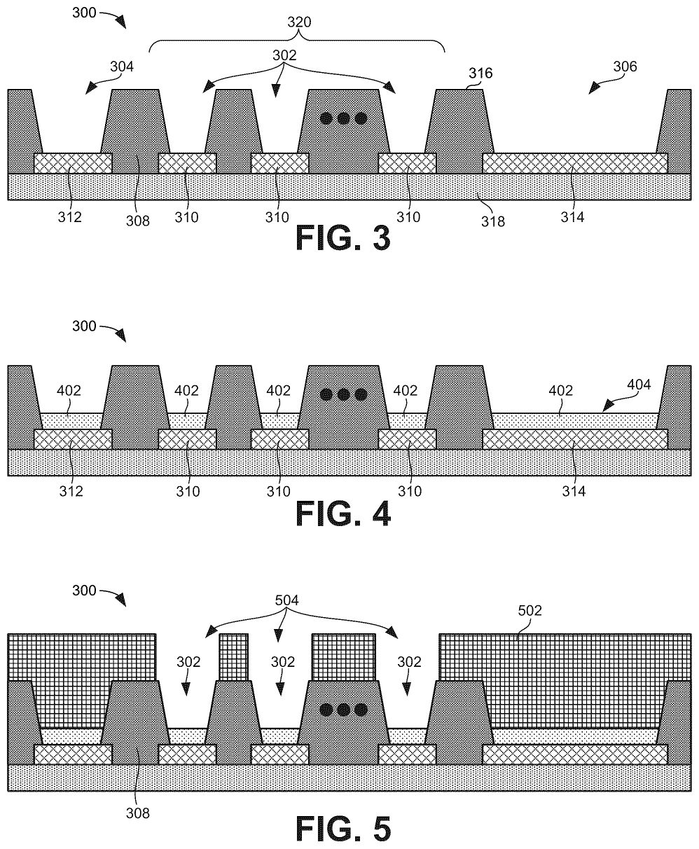

In this example, both the first plurality of connectors 218 and the second plurality of connectors 220 are positioned within openings distributed along respective first and second solder resist layers 222, 224 respectively defining the inner and outer surfaces 122, 124 of the substrate 110. In FIG. 2, the first and second plurality of connectors 218, 220 include tin that is in direct contact (e.g., directly adjacent) with the metal (e.g., copper) pads 226 at the base of openings. That is, the surface finish on the metal pads 226 does not include any discrete layers of material other than tin (or tin-based alloys) that separate the tin defining the connectors 218, 220 from the metal pads 226. Rather, as discussed further below, the surface finish for the metal pads 226 includes tin. The tin-based surface finish on the metal pads 226 is not demarcated in FIG. 2 because additional material (e.g., tin) is added onto the initial surface finish (also including tin) to define the complete connectors 218, 220 in which the surface finish extends continuously from the metal pads 226 to an outer (e.g., exposed) surface of the connectors 218, 220. However, other types of openings in the solder resist layers 222, 224 may also include the tin-based surface finish without the addition of more tin to fill the corresponding openings as detailed below in connection with FIGS. 3-8.

FIGS. 3-8 illustrate different stages in an example process of manufacturing an example package substrate 300 that may be implemented for the example substrate 110 of FIGS. 1 and/or 2. For purposes of explanation, certain details are shown in FIGS. 3-8 that are not shown in FIGS. 1 and 2, and certain details shown in FIGS. 1 and 2 are omitted in FIGS. 3-8. However, in some examples, some or all of the features of the example substrate 110 shown and described in connection with FIGS. 1 and 2 may be applied to the example substrate 300 of FIGS. 3-8. Likewise, in some examples, some or all of the features of the example substrate 300 shown and described in connection with FIGS. 3-8 may be applied to the example substrate 110 shown in FIGS. 1 and 2.

FIG. 3 illustrates the stage of manufacture of the example package substrate 300 after multiple different types of openings 302, 304, 306 (e.g., solder resist openings) have been provided in a solder resist layer 308 to expose corresponding metal pads 310, 312, 314 (e.g., copper contacts) at the base of the openings 302, 304, 306. For purposes of explanation, the solder resist layer 308 defines an inner surface 316 of the substrate 300 (e.g., comparable to the inner surface 122 of FIGS. 1 and 2) onto which a semiconductor die may be attached. The copper pads 310, 312, 314 are provided on an underlying layer of dielectric material 318 associated with a build-up layer of the package substrate 300. However, for purposes of simplicity, metal vias within the layer of dielectric material 318 and other layers of material below the layer of dielectric material 318 have been omitted. In some examples, the substrate 300 may include an outer surface (e.g., comparable to the outer surface 134 of FIGS. 1 and 2) that is opposite the inner surface 316. The outer surface of the substrate 300 may have openings similar to the openings 302, 304, 306 shown for the inner surface 316. Accordingly, while only the inner surface 316 is shown and described, examples disclosed herein apply equally to outer surfaces of the example package substrate 300.

In FIG. 3, the different types of openings 302, 304, 306 in the solder resist layer 308 serve different purposes. In this example, there are a plurality of the first openings 302 arranged in an array 320 that serve as first level interconnects 802 (FIG. 8) for electrically and mechanically coupling a semiconductor die to the example substrate 300. Thus, the example array 320 of first openings 302 can serve as the basis for the first plurality of connectors 218 shown and described in connection with FIG. 2. The second opening 304 (and the associated second metal pad 312) in the solder resist layer 308 serves as a fiducial marker 804 (FIG. 8) to facilitate alignment of a semiconductor die with the substrate 300 when the die is being attached to the first level interconnects 802 associated with the array 320 of the first openings 302. The second opening 304 can be any suitable size and/or shape and located at any suitable location on the surface 316 of the substrate 300. Further, in some examples, there may be more than one fiducial marker 804. The third opening 306 (and the associated third metal pad 314) serves as a die-side capacitor pad 806 (FIG. 8) to which a die-side capacitor may be attached. In some examples, there may be more than one die-side capacitor pad 806. As shown in FIG. 3, the contact pad (e.g., the third metal pad 314) for a die-side capacitor is much larger than the contact pads (e.g., the first metal pads 310) for the first level interconnects 802. One or more similar openings on the outer surface of the substrate 300 can define land-side capacitor pad(s) to which a land-side capacitor may be attached.

Any suitable processes (presently known or subsequently developed) may be employed to fabricate the example package substrate 300 up to the point represented by FIG. 3. Specifically, the stage of manufacture represented in FIG. 3 is just before a surface finish is applied to the exposed portions of the metal pads 310, 312, 314. As described above, a traditional surface finish includes layers of nickel, palladium, and gold. Typically, these materials are deposited using an electroless plating process that involves a rock and shock operation to release hydrogen bubbles within the materials. Examples disclosed here do not deposit such a surface finish. That is, at least one of nickel, palladium, or gold is omitted. In some examples, all three materials are omitted from the surface finish. Instead, a surface finish based on tin is used as represented in FIG. 4. Specifically, as shown in FIG. 4, a layer of tin 402 is plated onto the exposed surfaces of the metal pads 310, 312, 314. In some examples, the layer of tin 402 is substantially pure tin. In some examples, the layer of tin 402 is a tin-based alloy. The layer of tin serves as a surface finish 404 for the metal pads 310, 312, 314. In this example, the surface finish does not include a layer of nickel disposed therein, does not include a layer of palladium disposed therein, and does not include a layer of gold disposed therein.

In some examples, the tin is deposited using an electroless plating process. More particularly, in some examples, an immersion tin plating process is used. Additionally or alternatively, in some examples, an autocatalytic tin plating process is used. An advantage of such tin-based electroless plating processes is that they can be completed without a rock and shock operation. As a result, there is less risk of mechanical damage to components in the package substrate 300 (e.g., a glass core). Furthermore, the tin-based surface finish disclosed herein does not require any additional process operations relative to the traditional electroless plating of nickel, palladium, and gold. Rather, it replaces the traditional electroless plating process with a new electroless plating process based on a different material.

After the deposition of a surface finish 404 of tin 402 (represented in FIG. 4), additional processing is needed to complete the formation of solder bumps corresponding to the first level interconnects 802 associated with the array 320 of openings 302. The tin-based surface finish 404 disclosed herein is compatible with traditional fabrication processes. As such, the use of the example surface finish disclosed herein provides the advantages detailed above without the need to redesign subsequent operations. These subsequent operations are represented in FIGS. 5-8.

Specifically, FIG. 5 represents the deposition of a dry film resist 502 that has been lithographically patterned with openings 504 to uncover the first openings 302 in the solder resist layer 308. FIG. 6 represents the deposition of additional tin 602 onto the initial tin deposited in connection with the surface finish 404 discussed above in connection with FIG. 4. That is, the additional tin 602 is an extension of the initial tin 402 shown in FIG. 4. In some examples, the additional tin 602 has the same or similar composition as the initial tin 402. That is, in some examples, the additional tin 602 is substantially pure tin. In other examples, the additional tin 602 is a tin-based alloy. Significantly, the tin 402 in the second and third openings 304, 306 is not expanded or extending during this process because these portions of the tin 402 are covered by the dry film resist 502. FIG. 7 represents the stage of manufacture after the removal of the dry film resist 502 from the example substrate 300. Finally, FIG. 8 represents the example package substrate 300 after a reflow process to shape the tin 602 into round bumps 808 corresponding to the final shape for the first level interconnects 802. The reflow process involves heating the tin 602 to a liquid (e.g., above its melting point) such that the surface tension of the liquid tin reshapes the tin 602 into the round shape with a convex outer surface. Inasmuch as the surface finish 404 in the second and third openings 304, 306 is made of tin 402, the surface finish 404 will also melt during the reflow process and change shape to include an exposed surface (e.g., outer surface) that is convex (e.g., domed, rounded, etc.), as shown in FIG. 8. Thus, the final construction of the fiducial marker 804 and the die-side capacitor pad 806 is shown in FIG. 8. In particular, as shown in FIG. 8, both the fiducial marker 804 and the die-side capacitor pad 806 includes a metal base (e.g., a copper base corresponding to ones of the metal pads 312, 314) below the corresponding solder resist openings 304, 306 with the tin 402 (corresponding to the surface finish 404 added as shown in FIG. 4), 602 in direct contact with the metal base. Further, the tin 402 extends continuously from the metal base to an exposed surface (e.g., outer surface) of the tin 402 within the solder resist openings 304, 306. Tin is relatively reflective and, therefore, can reliably serve as a fiducial marker 804 to reflect light when placing a semiconductor die in alignment with the first level interconnects 802.

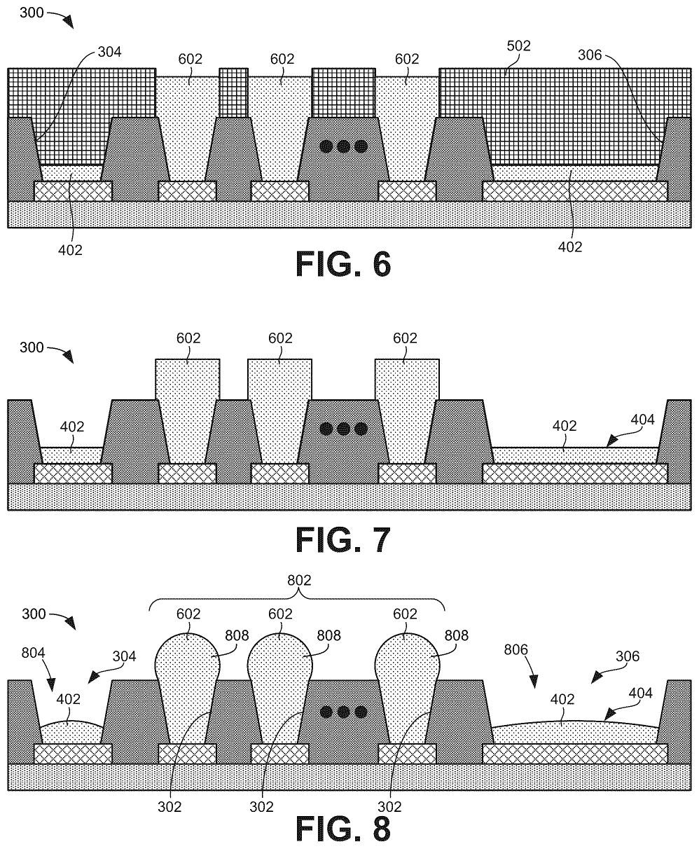

FIG. 9 is a flowchart illustrating an example method of manufacturing any one of the example package substrates 110, 300 of FIGS. 1-8. Although the example method of manufacture is described with reference to the flowchart illustrated in FIG. 9, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example process begins at block 902 by providing a package substrate with openings in a solder resist layer on an outer surface of the substrate. In some examples, the process can apply to both surfaces (e.g., inner and outer surfaces) of a package substrate at the same time. Different ones of the openings in the solder resist layer may correspond to first level interconnects, capacitor pads, and/or fiducial markers. At block 904, the process involves depositing a surface finish of tin onto exposed portions of metal pads at the base of the openings in the solder resist layer. In some examples, the surface finish is deposited using an electroless plating process (e.g., immersion plating and/or autocatalytic plating). At block 906, the process involves depositing a dry film resist over the openings in the solder resist layer. At block 908, the process involves patterning the dry film resist to uncover the surface finish of tin in selective ones of the openings in the solder resist layer. In some examples, the selective ones of the openings correspond to first level interconnects. At block 910, the process involves depositing tin onto the exposed surface finish of tin. Unlike the deposition of the surface finish of tin at block 904, in some examples, the deposition of tin at block 910 is through an electrolytic plating process. At block 912, the process involves removing the dry film resist. As a result, the surface finish of tin in the openings that remained covered after the patterning of the dry film resist at block 908 will be exposed. At block 914, the process involves heating the tin during a reflow process. The reflow process melts the tin into a liquid state to be reshaped with a convex outer surface. Thereafter, the example process of FIG. 9 ends.

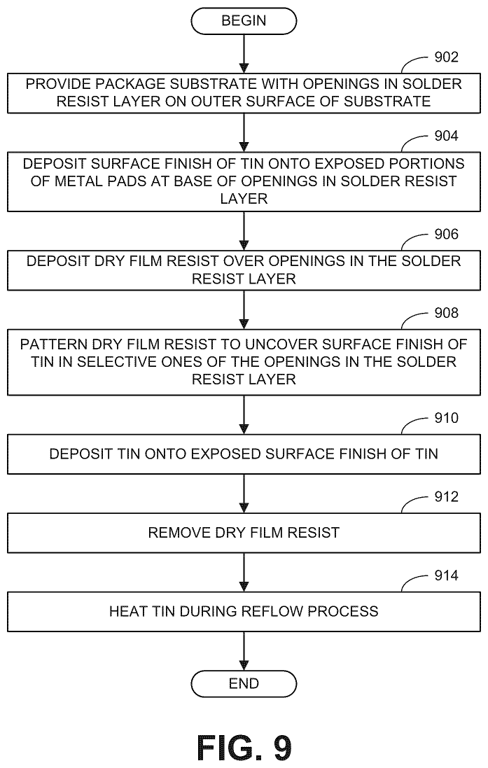

The example package substrates 110, 300 of FIGS. 1-8, and/or, more generally, the example IC package 100 of FIG. 1 disclosed herein may be included in any suitable electronic component. FIGS. 10-13 illustrate various examples of apparatus that may include or be included in the IC package 100 disclosed herein.

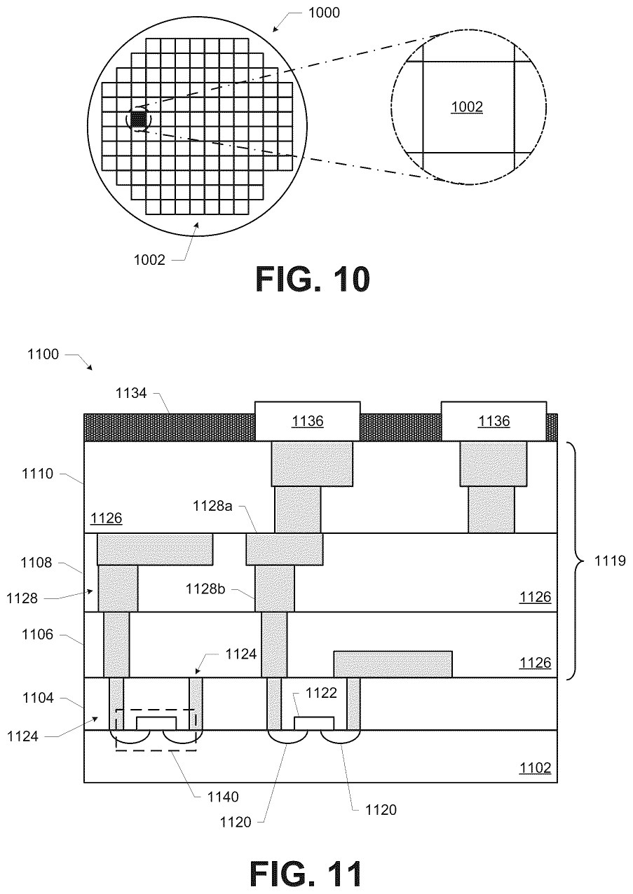

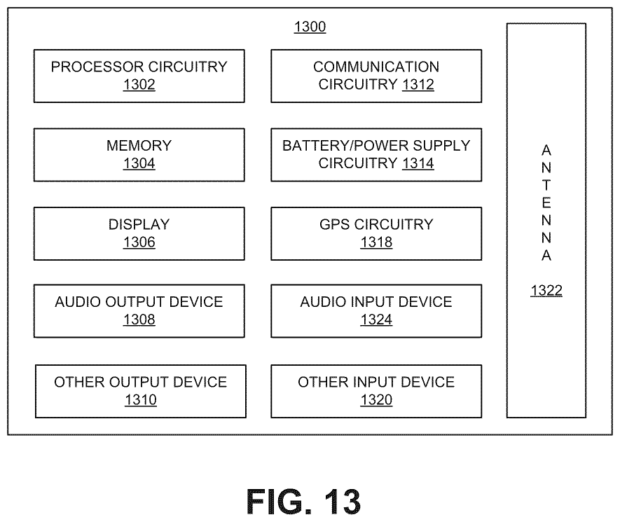

FIG. 10 is a top view of a wafer 1000 and dies 1002 that may be included in the IC package 100 of FIG. 1 (e.g., as any suitable ones of the semiconductor dies 106, 108). The wafer 1000 may be composed of semiconductor material and may include one or more dies 1002 having circuitry. Each of the dies 1002 may be a repeating unit of a semiconductor product. After the fabrication of the semiconductor product is complete, the wafer 1000 may undergo a singulation process in which the dies 1002 are separated from one another to provide discrete “chips.” The die 1002 may include one or more transistors (e.g., some of the transistors 1140 of FIG. 11, discussed below), supporting circuitry to route electrical signals to the transistors, passive components (e.g., traces, resistors, capacitors, inductors, and/or other circuitry), and/or any other components. In some examples, the die 1002 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1002. For example, a memory array formed by multiple memory circuits may be formed on a same die 1002 as programmable circuitry (e.g., the processor circuitry 1302 of FIG. 13) or other logic circuitry. Such memory may store information for use by the programmable circuitry. The example IC package 100 disclosed herein may be manufactured using a die-to-wafer assembly technique in which some dies 106, 108 are attached to a wafer 1000 that include others of the dies 106, 108, and the wafer 1000 is subsequently singulated.

FIG. 11 is a cross-sectional side view of an IC device 1100 that may be included in the example IC package 100 (e.g., in any one of the dies 106, 108). One or more of the IC devices 1100 may be included in one or more dies 1002 (FIG. 10). The IC device 1100 may be formed on a die substrate 1102 (e.g., the wafer 1000 of FIG. 10) and may be included in a die (e.g., the die 1002 of FIG. 10). The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some examples, the die substrate 1102 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an IC device 1100 may be used. The die substrate 1102 may be part of a singulated die (e.g., the dies 1002 of FIG. 10) or a wafer (e.g., the wafer 1000 of FIG. 10).

The IC device 1100 may include one or more device layers 1104 disposed on or above the die substrate 1102. The device layer 1104 may include features of one or more transistors 1140 (e.g., metal oxide semiconductor field-effect transistors (MOSFETs)) formed on the die substrate 1102. The device layer 1104 may include, for example, one or more source and/or drain (S/D) regions 1120, a gate 1122 to control current flow between the S/D regions 1120, and one or more S/D contacts 1124 to route electrical signals to/from the S/D regions 1120. The transistors 1140 may include additional features not depicted for the sake of clarity, such as device isolation regions, gate contacts, and the like. The transistors 1140 are not limited to the type and configuration depicted in FIG. 11 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1140 may include a gate 1122 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1140 along the source-channel-drain direction, the gate electrode may consist of a U-shaped structure that includes a bottom portion substantially parallel to the surface of the die substrate 1102 and two sidewall portions that are substantially perpendicular to the top surface of the die substrate 1102. In other examples, at least one of the metal layers that form the gate electrode may simply be a planar layer that is substantially parallel to the top surface of the die substrate 1102 and does not include sidewall portions substantially perpendicular to the top surface of the die substrate 1102. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of each transistor 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be carried out to fill the recesses with material that is used to fabricate the S/D regions 1120. In some implementations, the S/D regions 1120 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1120 may be formed using one or more alternate semiconductor materials such as germanium or a group III-V material or alloy. In further examples, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-2010). For example, electrically conductive features of the device layer 1104 (e.g., the gate 1122 and the S/D contacts 1124) may be electrically coupled with the interconnect structures 1128 of the interconnect layers 1106-2010. The one or more interconnect layers 1106-2010 may form a metallization stack (also referred to as an “ILD stack”) 1119 of the IC device 1100.

The interconnect structures 1128 may be arranged within the interconnect layers 1106-2010 to route electrical signals according to a wide variety of designs (in particular, the arrangement is not limited to the particular configuration of interconnect structures 1128 depicted in FIG. 11). Although a particular number of interconnect layers 1106-2010 is depicted in FIG. 11, examples of the present disclosure include IC devices having more or fewer interconnect layers than depicted.

In some examples, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page from the perspective of FIG. 11. The vias 1128b may be arranged to route electrical signals in a direction of a plane that is substantially perpendicular to the surface of the die substrate 1102 upon which the device layer 1104 is formed. In some examples, the vias 1128b may electrically couple lines 1128a of different interconnect layers 1106-2010 together.

The interconnect layers 1106-2010 may include a dielectric material 1126 disposed between the interconnect structures 1128, as shown in FIG. 11. In some examples, the dielectric material 1126 disposed between the interconnect structures 1128 in different ones of the interconnect layers 1106-2010 may have different compositions; in other examples, the composition of the dielectric material 1126 between different interconnect layers 1106-2010 may be the same.

A first interconnect layer 1106 (referred to as Metal 1 or “M1”) may be formed directly on the device layer 1104. In some examples, the first interconnect layer 1106 may include lines 1128a and/or vias 1128b, as shown. The lines 1128a of the first interconnect layer 1106 may be coupled with contacts (e.g., the S/D contacts 1124) of the device layer 1104.

A second interconnect layer 1108 (referred to as Metal 2 or “M2”) may be formed directly on the first interconnect layer 1106. In some examples, the second interconnect layer 1108 may include vias 1128b to couple the lines 1128a of the second interconnect layer 1108 with the lines 1128a of the first interconnect layer 1106. Although the lines 1128a and the vias 1128b are structurally delineated with a line within each interconnect layer (e.g., within the second interconnect layer 1108) for the sake of clarity, the lines 1128a and the vias 1128b may be structurally and/or materially contiguous (e.g., simultaneously filled during a dual-damascene process) in some examples.

A third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some examples, the interconnect layers that are “higher up” in the metallization stack 1119 in the IC device 1100 (i.e., further away from the device layer 1104) may be thicker.

The IC device 1100 may include a solder resist material 1134 (e.g., polyimide or similar material) and one or more conductive contacts 1136 formed on the interconnect layers 1106-2010. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to other external devices. For example, solder bonds may be formed on the one or more conductive contacts 1136 to mechanically and/or electrically couple a chip including the IC device 1100 with another component (e.g., a circuit board). The IC device 1100 may include additional or alternate structures to route the electrical signals from the interconnect layers 1106-2010; for example, the conductive contacts 1136 may include other analogous features (e.g., posts) that route the electrical signals to external components.

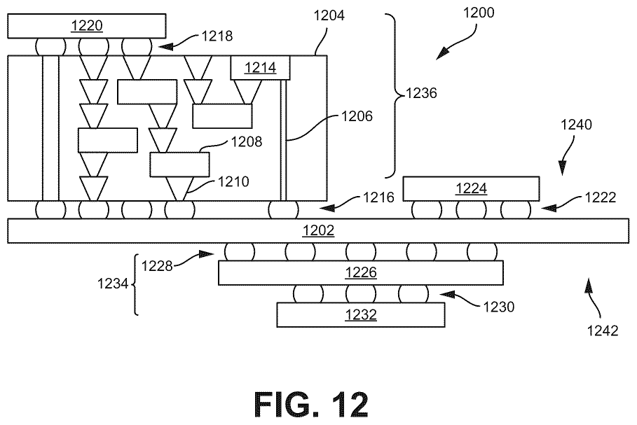

FIG. 12 is a cross-sectional side view of an IC device assembly 1200 that may include the IC package 100 disclosed herein. In some examples, the IC device assembly corresponds to the IC package 100. The IC device assembly 1200 includes a number of components disposed on a circuit board 1202 (which may be, for example, a motherboard). The IC device assembly 1200 includes components disposed on a first face 1240 of the circuit board 1202 and an opposing second face 1242 of the circuit board 1202; generally, components may be disposed on one or both faces 1240 and 1242. Any of the IC packages discussed below with reference to the IC device assembly 1200 may take the form of the example IC package 100 of FIG. 1.

In some examples, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other examples, the circuit board 1202 may be a non-PCB substrate. In some examples, the circuit board 1202 may be, for example, the circuit board 102 of FIG. 1.

The IC device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), male and female portions of a socket, an adhesive, an underfill material, and/or any other suitable electrical and/or mechanical coupling structure.

The package-on-interposer structure 1236 may include an IC package 1220 coupled to an interposer 1204 by coupling components 1218. The coupling components 1218 may take any suitable form for the application, such as the forms discussed above with reference to the coupling components 1216. Although a single IC package 1220 is shown in FIG. 12, multiple IC packages may be coupled to the interposer 1204; indeed, additional interposers may be coupled to the interposer 1204. The interposer 1204 may provide an intervening substrate used to bridge the circuit board 1202 and the IC package 1220. The IC package 1220 may be or include, for example, a die (the die 1002 of FIG. 10), an IC device (e.g., the IC device 1100 of FIG. 11), or any other suitable component. Generally, the interposer 1204 may spread a connection to a wider pitch or reroute a connection to a different connection. For example, the interposer 1204 may couple the IC package 1220 (e.g., a die) to a set of BGA conductive contacts of the coupling components 1216 for coupling to the circuit board 1202. In the example illustrated in FIG. 12, the IC package 1220 and the circuit board 1202 are attached to opposing sides of the interposer 1204; in other examples, the IC package 1220 and the circuit board 1202 may be attached to a same side of the interposer 1204. In some examples, three or more components may be interconnected by way of the interposer 1204.

In some examples, the interposer 1204 may be formed as a PCB, including multiple metal layers separated from one another by layers of dielectric material and interconnected by electrically conductive vias. In some examples, the interposer 1204 may be formed of an epoxy resin, a fiberglass-reinforced epoxy resin, an epoxy resin with inorganic fillers, a ceramic material, or a polymer material such as polyimide. In some examples, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The IC device assembly 1200 may include an IC package 1224 coupled to the first face 1240 of the circuit board 1202 by coupling components 1222. The coupling components 1222 may take the form of any of the examples discussed above with reference to the coupling components 1216, and the IC package 1224 may take the form of any of the examples discussed above with reference to the IC package 1220.

The IC device assembly 1200 illustrated in FIG. 12 includes a package-on-package structure 1234 coupled to the second face 1242 of the circuit board 1202 by coupling components 1228. The package-on-package structure 1234 may include a first IC package 1226 and a second IC package 1232 coupled together by coupling components 1230 such that the first IC package 1226 is disposed between the circuit board 1202 and the second IC package 1232. The coupling components 1228, 1230 may take the form of any of the examples of the coupling components 1216 discussed above, and the IC packages 1226, 1232 may take the form of any of the examples of the IC package 1220 discussed above. The package-on-package structure 1234 may be configured in accordance with any of the package-on-package structures known in the art.

FIG. 13 is a block diagram of an example electrical device 1300 that may include one or more of the example IC packages 100 of FIG. 1. For example, any suitable ones of the components of the electrical device 1300 may include one or more of the device assemblies 1200, IC devices 1100, or dies 1002 disclosed herein, and may be arranged in the example IC package 100. A number of components are illustrated in FIG. 13 as included in the electrical device 1300, but any one or more of these components may be omitted or duplicated, as suitable for the application. In some examples, some or all of the components included in the electrical device 1300 may be attached to one or more motherboards. In some examples, some or all of these components are fabricated onto a single system-on-a-chip (SoC) die.

Additionally, in various examples, the electrical device 1300 may not include one or more of the components illustrated in FIG. 13, but the electrical device 1300 may include interface circuitry for coupling to the one or more components. For example, the electrical device 1300 may not include a display 1306, but may include display interface circuitry (e.g., a connector and driver circuitry) to which a display 1306 may be coupled. In another set of examples, the electrical device 1300 may not include an audio input device 1324 (e.g., microphone) or an audio output device 1308 (e.g., a speaker, a headset, earbuds, etc.), but may include audio input or output device interface circuitry (e.g., connectors and supporting circuitry) to which an audio input device 1324 or audio output device 1308 may be coupled.

The electrical device 1300 may include programmable circuitry 1302 (e.g., one or more processing devices). The programmable circuitry 1302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1300 may include a memory 1304, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1304 may include memory that shares a die with the programmable circuitry 1302. This memory may be used as cache memory and may include embedded dynamic random access memory (eDRAM) or spin transfer torque magnetic random access memory (STT-MRAM).

In some examples, the electrical device 1300 may include a communication chip 1312 (e.g., one or more communication chips). For example, the communication chip 1312 may be configured for managing wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1312 may implement any of a number of wireless standards or protocols, including but not limited to Institute for Electrical and Electronic Engineers (IEEE) standards including Wi-Fi (IEEE 808.11 family), IEEE 808.16 standards (e.g., IEEE 808.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 808.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 808.16 standards. The communication chip 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 1G, 5G, and beyond. The communication chip 1312 may operate in accordance with other wireless protocols in other examples. The electrical device 1300 may include an antenna 1322 to facilitate wireless communications and/or to receive other wireless communications (such as AM or FM radio transmissions).

In some examples, the communication chip 1312 may manage wired communications, such as electrical, optical, or any other suitable communication protocols (e.g., the Ethernet). As noted above, the communication chip 1312 may include multiple communication chips. For instance, a first communication chip 1312 may be dedicated to shorter-range wireless communications such as Wi-Fi or Bluetooth, and a second communication chip 1312 may be dedicated to longer-range wireless communications such as global positioning system (GPS), EDGE, GPRS, CDMA, WiMAX, LTE, EV-DO, or others. In some examples, a first communication chip 1312 may be dedicated to wireless communications, and a second communication chip 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display 1306 (or corresponding interface circuitry, as discussed above). The display 1306 may include any visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any device that generates an audible indicator, such as speakers, headsets, or earbuds.

The electrical device 1300 may include an audio input device 1324 (or corresponding interface circuitry, as discussed above). The audio input device 1324 may include any device that generates a signal representative of a sound, such as microphones, microphone arrays, or digital instruments (e.g., instruments having a musical instrument digital interface (MIDI) output).

The electrical device 1300 may include GPS circuity 1318. The GPS circuity 1318 may be in communication with a satellite-based system and may receive a location of the electrical device 1300, as known in the art.

The electrical device 1300 may include any other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include any other input device 1320 (or corresponding interface circuitry, as discussed above). Examples of the other input device 1320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1300 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Further examples and combinations thereof include the following:

Example 1 includes an integrated circuit (IC) package substrate comprising a first solder resist layer, a second solder resist layer opposite the first solder resist layer, and a fiducial marker including tin in an opening in the first solder resist layer.

Example 2 includes the IC package substrate of example 1, further including a glass core between the first and second solder resist layers.

Example 3 includes the IC package substrate of example 1, further including a copper pad at a base of the opening, the copper pad including a surface finish, the surface finish corresponding to the tin.

Example 4 includes the IC package substrate of example 1, further including a metal base below the opening, the fiducial marker having an exposed surface defined by the tin within the opening, the tin different than the metal base, the tin extending from the metal base to the exposed surface.

Example 5 includes the IC package substrate of example 1, wherein an exposed surface of the fiducial marker has a convex surface.

Example 6 includes the IC package substrate of example 1, wherein the opening is one of a plurality of openings in the first solder resist layer, the IC package substrate further including a plurality of metal pads to electrically interconnect with a plurality of contacts on a semiconductor die, and the plurality of openings in the first solder resist layer, the plurality of openings aligned with the plurality of metal pads and filled with additional tin to electrically couple the plurality of metal pads with the plurality of contacts, the additional tin in direct contact with the plurality of metal pads.

Example 7 includes the IC package substrate of example 1, wherein the opening is a first opening, the IC package substrate further including a die-side capacitor pad in a second opening in the first solder resist layer.

Example 8 includes the IC package substrate of example 7, wherein the die-side capacitor pad includes a base including copper and a layer including tin, the layer on the base.

Example 9 includes the IC package substrate of example 8, wherein the layer is in contact with the base.

Example 10 includes an integrated circuit (IC) package comprising a semiconductor die, a package substrate supporting the semiconductor die, and an opening in a surface of the package substrate, a metal pad at a base of the opening, and a surface finish on the metal pad, the surface finish having a domed shape.

Example 11 includes the IC package of example 10, wherein the surface finish includes tin.

Example 12 includes the IC package of example 11, wherein the surface finish is associated with a fiducial marker, the surface finish extending from the metal pad to an exposed surface of the fiducial marker.

Example 13 includes the IC package of example 10, wherein the surface finish does not include a layer of nickel disposed therein.

Example 14 includes the IC package of example 10, wherein the package substrate includes a glass core.

Example 15 includes the IC package of example 10, further including a plurality of bumps to electrically couple the semiconductor die to a corresponding plurality of contact pads on the package substrate, the bumps defined by tin in direct contact with the contact pads.

Example 16 includes the IC package of example 10, wherein the surface finish is a first surface finish, the IC package further including at least one of a die-side capacitor pad or a land-side capacitor pad on the package substrate, the at least one of the die-side capacitor pad or the land-side capacitor pad defined by a metal base with a second surface finish including tin in direct contact with the metal base.

Example 17 includes a method comprising providing openings within a solder resist layer of a package substrate for an integrated circuit (IC) package, the openings to expose metal pads, a first one of the openings defining a fiducial marker, and depositing a surface finish onto ones of the metal pads in ones of the openings, the ones of the openings including the first opening, the surface finish including tin.

Example 18 includes the method of example 17, wherein the depositing of the surface finish is accomplished through electroless plating.

Example 19 includes the method of example 17, wherein the depositing of the surface finish is accomplished without a rock and shock operation.

Example 20 includes the method of example 17, further including constructing the package substrate with a glass core.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit (IC) package substrate comprising:
a first solder resist layer;
a second solder resist layer opposite the first solder resist layer; and
a fiducial marker including tin in an opening in the first solder resist layer.

2. The IC package substrate of claim 1, further including a glass core between the first and second solder resist layers.

3. The IC package substrate of claim 1, further including a copper pad at a base of the opening, the copper pad including a surface finish, the surface finish corresponding to the tin.

4. The IC package substrate of claim 1, further including a metal base below the opening, the fiducial marker having an exposed surface defined by the tin within the opening, the tin different than the metal base, the tin extending from the metal base to the exposed surface.

5. The IC package substrate of claim 1, wherein an exposed surface of the fiducial marker has a convex surface.

6. The IC package substrate of claim 1, wherein the opening is one of a plurality of openings in the first solder resist layer, the IC package substrate further including:
a plurality of metal pads to electrically interconnect with a plurality of contacts on a semiconductor die; and
the plurality of openings in the first solder resist layer, the plurality of openings aligned with the plurality of metal pads and filled with additional tin to electrically couple the plurality of metal pads with the plurality of contacts, the additional tin in direct contact with the plurality of metal pads.

7. The IC package substrate of claim 1, wherein the opening is a first opening, the IC package substrate further including a die-side capacitor pad in a second opening in the first solder resist layer.

8. The IC package substrate of claim 7, wherein the die-side capacitor pad includes a base including copper and a layer including tin, the layer on the base.

9. The IC package substrate of claim 8, wherein the layer is in contact with the base.

10. An integrated circuit (IC) package comprising:
a semiconductor die;
a package substrate supporting the semiconductor die; and
an opening in a surface of the package substrate;
a metal pad at a base of the opening; and
a surface finish on the metal pad, the surface finish having a domed shape.

11. The IC package of claim 10, wherein the surface finish includes tin.

12. The IC package of claim 11, wherein the surface finish is associated with a fiducial marker, the surface finish extending from the metal pad to an exposed surface of the fiducial marker.

13. The IC package of claim 10, wherein the surface finish does not include a layer of nickel disposed therein.

14. The IC package of claim 10, wherein the package substrate includes a glass core.

15. The IC package of claim 10, further including a plurality of bumps to electrically couple the semiconductor die to a corresponding plurality of contact pads on the package substrate, the bumps defined by tin in direct contact with the contact pads.

16. The IC package of claim 10, wherein the surface finish is a first surface finish, the IC package further including at least one of a die-side capacitor pad or a land-side capacitor pad on the package substrate, the at least one of the die-side capacitor pad or the land-side capacitor pad defined by a metal base with a second surface finish including tin in direct contact with the metal base.

17. A method comprising:
providing openings within a solder resist layer of a package substrate for an integrated circuit (IC) package, the openings to expose metal pads, a first one of the openings defining a fiducial marker; and
depositing a surface finish onto ones of the metal pads in ones of the openings, the ones of the openings including the first opening, the surface finish including tin.

18. The method of claim 17, wherein the depositing of the surface finish is accomplished through electroless plating.

19. The method of claim 17, wherein the depositing of the surface finish is accomplished without a rock and shock operation.

20. The method of claim 17, further including constructing the package substrate with a glass core.
